(19) United States
(12) Patent Application Publication
(10) Pub. No.: US 2026/0369963 A1
(43) Pub. Date: Nov. 19, 2026

(54) METHOD FOR MANUFACTURING SURFACE-EMITTING SEMICONDUCTOR LASER ELEMENT, AND SURFACE-EMITTING SEMICONDUCTOR LASER ELEMENT

(71) Applicants: KYOTO UNIVERSITY, Kyoto-shi, Kyoto (JP); STANLEY ELECTRIC CO., LTD., Meguro-ku, Tokyo (JP)

(72) Inventors: Susumu NODA, Kyoto (JP); Tomoaki KOIZUMI, Tokyo (JP); Kei EMOTO, Tokyo (JP)

(73) Assignees: KYOTO UNIVERSITY, Kyoto-shi, Kyoto (JP); STANLEY ELECTRIC CO., LTD., Meguro-ku, Tokyo (JP)

(21) Appl. No.: 19/470,673

(22) PCT Filed: Mar. 18, 2024
(86) PCT No.: PCT/JP2024/010552

§ 371 Date: Sep. 29, 2025

(30) Foreign Application Priority Data
Mar. 30, 2023 (JP) 2023-055673

(51) Int. Cl. H01S 5/11; H01S 5/028; H01S 5/042; H01S 5/343

(52) U.S. Cl. CPC H01S 5/11; H01S 5/028; H01S 5/04253; H01S 5/34333

(57) ABSTRACT

A method includes (a) forming a hole formation preparation layer on a substrate; (b) forming holes in the hole formation preparation layer, the holes being two-dimensionally disposed at respective lattice points, thereby forming a hole formation layer; (c) oxidizing a surface of the hole formation layer to form an oxide film and thereafter removing the oxide film; (d) performing facet growth to close the holes, thereby forming a first embedded layer; (e) performing growth of a second embedded layer that flatly embeds the first embedded layer, thereby forming a guide layer including an air hole layer having air holes corresponding to the holes; and (f) performing crystal growth of a semiconductor layer including an active layer on the guide layer.

### TECHNICAL FIELD

The present invention relates to a method for manufacturing a surface-emitting semiconductor laser element having a photonic crystal, and to a surface-emitting semiconductor laser element.

### BACKGROUND ART

Recently, development of photonic-crystal surface-emitting lasers (PCSELs) using photonic crystals (PCs) has been advancing.

For example, Patent Literature 1 discloses a method in which, to enhance the diffraction effect in an air hole layer in a photonic crystal laser and achieve high resonance effect, air holes having a hexagonal prismatic structure with side surface with {10-10} facets are embedded in a group III nitride semiconductor layer by using facet-selective growth. It is described that, by the method, a photonic crystal laser element is realized which includes a photonic crystal with a high filling factor and a high optical confinement factor.

Patent Literature 2 discloses a method in which, in a photonic crystal laser, air holes are embedded in a group III nitride semiconductor layer by using mass transport. It is described that, by the method, a photonic crystal laser is obtained which has a large coupling coefficient for a light wave propagating through the photonic crystal layer.

Patent Literature 3 discloses that a photonic crystal layer (air hole layer) is formed by performing first embedding growth that embeds holes by facet growth and second embedding growth that performs surface planarizing.

### CITATION LIST

### Patent Literature

### Patent Literature 1

Japanese Patent No. 7101370

### Patent Literature 2

Japanese Patent Laid-open No. 2020-38892

### Patent Literature 3

WO2018/155710 A1

### SUMMARY OF INVENTION

### Technical Problem

However, by using a method as disclosed in Patent Literature 1, it is possible to form an air hole layer with a sufficient air hole filling rate, but a layer thickness for embedding the air hole layer increases, which makes it impossible to reduce the distance between the air hole layer and the active layer. Thus, it is impossible to enhance the resonance effect in the air hole layer.

The inventor of the present application has found that when air holes are embedded and formed by using mass transport, significant surface roughness occurs due to a large amount of Si accumulated on a surface where the air holes are formed. Due to this surface roughness, there has been a problem in that growth of an active layer with high planarity and high quality on an embedded layer is encumbered and the air hole layer and the active layer cannot be brought sufficiently close to each other, which makes it impossible enhance the coupling efficiency between the air hole layer and the active layer.

Furthermore, when a high concentration of Si is introduced into a GaN film, point defects are likely to be introduced into the film, and from this perspective as well, it is preferable to remove the large amount of Si accumulated on the surface.

From the above, with conventional technologies, it is difficult to enhance resonance effect and reduction threshold current maintaining high output.

The present application invention is intended to provide a manufacturing method for manufacturing a surface-emitting semiconductor laser element in which an air hole layer and an active layer can be brought into proximity to enhance resonance effect and that includes a high-quality active layer and has a low threshold and high efficiency, and the surface-emitting semiconductor laser element.

### Solution to Problem

A method for manufacturing a surface-emitting semiconductor laser element according to one aspect of the present invention is a manufacturing method including:
(a) forming a hole formation preparation layer on a substrate;
(b) forming holes in the hole formation preparation layer, the holes being two-dimensionally disposed at respective lattice points, thereby forming a hole formation layer;
(c) oxidizing a surface of the hole formation layer to form an oxide film and thereafter removing the oxide film;
(d) performing facet growth to close the holes, thereby forming a first embedded layer;
(e) growing a second embedded layer that flatly embeds the first embedded layer, thereby forming a first guide layer including an air hole layer having air holes corresponding to the holes; and
(f) performing crystal growth of a semiconductor layer including an active layer on the first guide layer.

A method for manufacturing a surface-emitting semiconductor laser element according to another aspect of the present invention is a method for manufacturing a surface-emitting semiconductor laser element, the manufacturing method including:
(a) forming a hole formation preparation layer on a substrate;
(b) forming holes in the hole formation preparation layer, the holes being two-dimensionally disposed at respective lattice points, thereby forming a hole formation layer;
(c) oxidizing a surface of the hole formation layer to form an oxide film and thereafter removing the oxide film;
(d) performing facet growth to close the holes, thereby forming a first embedded layer;
(e) growing a second embedded layer that flatly embeds the first embedded layer, thereby forming a first guide layer including an air hole layer having air holes corresponding to the holes;
(f) performing planar etching on a surface of the first guide layer by annealing in a hydrogen atmosphere; and
(g) performing crystal growth of a semiconductor layer including an active layer on the planar-etched first guide layer.

A surface-emitting semiconductor laser element according to a further aspect of the present invention includes:
an n-type semiconductor layer;
a first guide layer formed on the n-type semiconductor layer and including an air hole layer having air holes two-dimensionally disposed at respective lattice points and an embedded layer formed on the air hole layer and closing the air holes;
a semiconductor layer formed on the embedded layer and including an active layer; and
a second guide layer formed on the semiconductor layer including the active layer,
in which a distance from upper surfaces of the air holes of the air hole layer to the active layer is 4 to 200 nm.

### BRIEF DESCRIPTION OF DRAWINGS

FIG. 1A is a cross-sectional view schematically illustrating an example of the structure of a PCSEL element of a first embodiment.

FIG. 1B is an enlarged cross-sectional view schematically illustrating air holes arrayed in an air hole layer illustrated in FIG. 1A.

FIG. 2A is a plan view schematically illustrating the upper surface of the PCSEL element.

FIG. 2B is a cross-sectional view schematically illustrating a section in a plane parallel to an n-side guide layer.

FIG. 2C is a plan view schematically illustrating the lower surface of the PCSEL element.

FIG. 3 is a flowchart illustrating a method for manufacturing the PCSEL element of the first embodiment.

FIG. 4 is a cross-sectional view schematically illustrating a section of the n-side guide layer at formation steps S0 to at S3 of an embedded layer.

FIG. 5 is a plan view schematically illustrating main openings and sub openings of a resist, and main holes and sub holes after etching.

FIG. 6 is a diagram schematically illustrating a section of the formed air hole layer, which is perpendicular to a central axis CX.

FIG. 7 illustrates depth-direction SIMS profiles of a PCSEL element (EMB) manufactured by performing a surface oxidation/oxide film removal process (step S1).

FIG. 8 illustrates depth-direction SIMS profiles of a PCSEL element (CMP) manufactured without performing the surface oxidation/oxide film removal process (step S1).

FIG. 9A is a cross-sectional view schematically illustrating an example of the structure of a PCSEL element of a second embodiment.

FIG. 9B is an enlarged cross-sectional view schematically illustrating the air hole layer in FIG. 9A and air holes arrayed in the air hole layer.

FIG. 10 is a flowchart illustrating a method for manufacturing the PCSEL element of the second embodiment.

FIG. 11 is a cross-sectional view schematically illustrating a section of the n-side guide layer at step S3A.

FIG. 12 is SEM images illustrating sections when the surfaces of substrates on which the embedded layer is regrown after the surface oxidation/oxide film removal process is performed are etched by H₂ annealing.

FIG. 13 is a diagram illustrating AFM images of the surfaces of samples (i) to (iv) illustrated in FIG. 12.

FIG. 14 is a graph plotting a surface roughness Ra in a 20 μm×20 μm region with respect to a thickness DE of the embedded layer after etching.

### DESCRIPTION OF EMBODIMENTS

Preferable embodiments of the present invention, which will be described below, may be modified and combined as appropriate. In the following description and accompanying drawings, parts that are identical or equivalent in effect are denoted by the same reference sign.

### First Embodiment

### 1. Structure of Photonic-Crystal Surface-Emitting Laser Element

A photonic-crystal surface-emitting laser element (PCSEL element) is a surface-emitting semiconductor laser element that includes a resonator layer in a direction parallel to a semiconductor light-emitting structure layer (n-side guide layer, light-emitting layer, and p-side guide layer) constituting a light-emitting element, and radiates coherent light in a direction perpendicular to the resonator layer.

Specifically, in the PCSEL element, a light wave propagating in a plane parallel to an air hole layer (photonic crystal layer) is diffracted by the diffraction effect of a photonic crystal to form a two-dimensional resonance mode, and is also diffracted in a direction perpendicular to the parallel plane. In other words, in the PCSEL element, the light extraction direction is perpendicular to the resonance direction (in-plane direction parallel to the air hole layer).

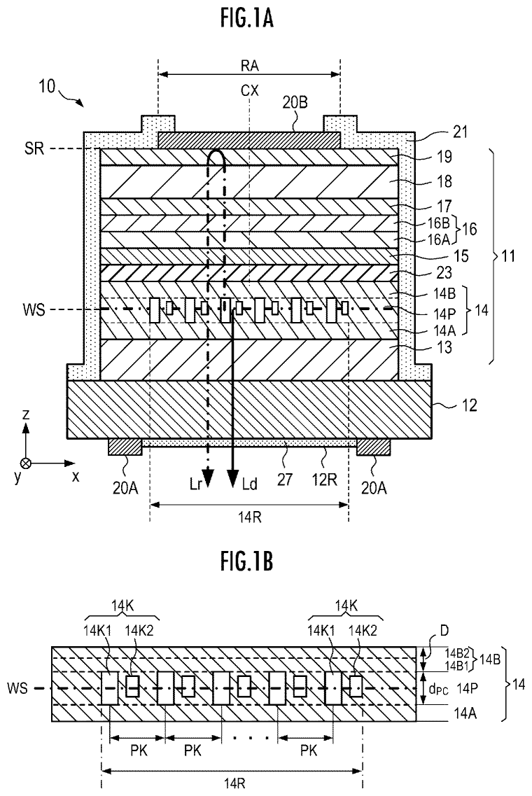

FIG. 1A is a cross-sectional view schematically illustrating an example of the structure of a photonic-crystal surface-emitting laser element (PCSEL element) 10 according to an embodiment of the present invention.

FIG. 1B is an enlarged cross-sectional view schematically illustrating an air hole layer 14P in FIG. 1A and air holes 14K arrayed in the air hole layer 14P.

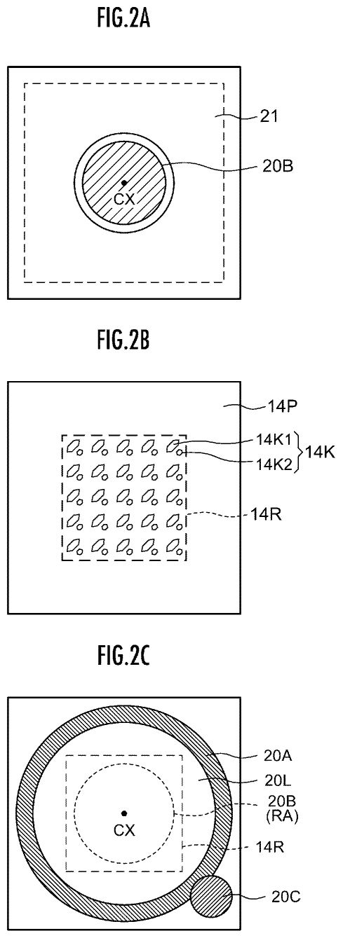

FIG. 2A is a plan view schematically illustrating the upper surface of the PCSEL element 10. FIG. 2B is a cross-sectional view schematically illustrating a section in a plane parallel to an n-side guide layer 14 of the air hole layer 14P, and FIG. 2C is a plan view schematically illustrating the lower surface of the PCSEL element 10.

As illustrated in FIG. 1A, a semiconductor structure layer 11 is formed on a light-transmissive element substrate 12. Note that semiconductor layers are stacked perpendicularly to a central axis CX of the semiconductor structure layer 11.

The semiconductor structure layer 11 is made of a hexagonal nitride semiconductor. In the present embodiment, the semiconductor structure layer 11 is made of, for example, a GaN-based semiconductor.

More specifically, the semiconductor structure layer 11 constituted by a plurality of semiconductor layers is formed on the element substrate 12 in the following order: an n-cladding layer (first cladding layer of a first conduction type) 13, the n-side guide layer (first guide layer) 14 that is a guide layer provided on the n-side, a light distribution adjustment layer 23, an active layer (ACT) 15, a p-side guide layer (second guide layer) 16 that is a guide layer provided on the p-side, an electron blocking layer (EBL) 17, p-cladding layer (second cladding layer of a second conduction type) 18, and a p-contact layer 19.

Note that a case will be described below where the first conduction type is n-type, and the second conduction type, which is the conduction type opposite to the first conduction type, is p-type, but the first conduction type and the second conduction type may be p-type and n-type, respectively.

The element substrate 12 is a hexagonal GaN single crystal substrate having a high transmittance for light radiated from the active layer 15. More specifically, the element substrate 12 is a hexagonal GaN single crystal substrate the principal surface (crystal growth surface) of which is a +c plane or {0001} plane in which Ga atoms are arrayed on the outermost surface. The back surface (light-emitting surface) is a −c plane or (000-1) plane in which N atoms are arrayed on the outermost surface. The −c plane has resistance to oxidation and the like and thus is suitable as a light-emitting surface.

The element substrate 12 is not limited thereto but is preferably what is called a just-cut substrate or, for example, a substrate the principal surface of which is offset by up to 1° approximately in the m-axis direction. For example, a substrate that is offset by up to 0.3 to 0.7° approximately in the m-axis direction can achieve mirror-surface growth under a wide range of growth conditions.

The substrate back surface facing the principal surface is a light-emitting surface and is a “−c” plane that is (000-1) face in which N atoms are arrayed on the outermost surface. The −c plane has resistance to oxidation and the like and thus is suitable as a light extraction surface.

The compositions, layer thicknesses, and other structures of respective semiconductor layers will be described below, but they are merely exemplary and may be modified and applied as appropriate.

The n-cladding layer 13 is, for example, an n-Al_{0.04}Ga_{0.96}N layer having an Al composition of 4% and has a layer thickness of 2 μm. The aluminum (Al) composition ratio is set such that the refractive index is lower than that of an adjacent layer (in other words, the n-side guide layer 14) on the active layer 15 side.

The n-side guide layer 14 is constituted by a lower guide layer 14A, the air hole layer 14P that serves as a photonic crystal layer (PC layer), and an embedded layer 14B. As illustrated in FIG. 1B, the air hole layer 14P has a layer thickness d_{PC}, and the embedded layer 14B has a thickness DE. For example, the thickness d_{PC} of the air hole layer 14P is 40 to 180 nm.

Note that, in the present specification, the air hole layer 14P is a layer part extending from upper ends of the air holes to their lower ends in the n-side guide layer 14 (refer to FIG. 1B). Accordingly, the layer thickness dec of the air hole layer 14P is equal to the height of the air holes.

The lower guide layer 14A is, for example, an n-GaN having a layer thickness of 100 to 400 nm. The air hole layer 14P is an n-GaN having a layer thickness (or height of the air holes 14K) of 40 to 180 nm.

The embedded layer 14B is made of n-GaN, n-InGaN, undoped GaN, or undoped InGaN. Alternatively, the embedded layer 14B may be a layer in which these semiconductor layers are stacked. The thickness DE of the embedded layer 14B is, for example, 4 to 200 nm. Note that the embedded layer 14B is constituted by a first embedded layer 14B1 and a second embedded layer 14B2. In other words, the embedded layer 14B is a stacked embedded layer in which the second embedded layer 14B2 is stacked on the first embedded layer 14B1.

The light distribution adjustment layer 23 as a hetero semiconductor layer (heterogeneous semiconductor layer) having a crystal composition different from that of the second embedded layer 14B2 and forming a heterostructure with the second embedded layer 14B2 is provided on the second embedded layer 14B2 as the surface layer of the embedded layer 14B.

Note that the light distribution adjustment layer 23 may be a semiconductor layer having the same conduction type as the second embedded layer 14B2, or at least one of them may be an i-layer (intrinsic semiconductor layer).

The light distribution adjustment layer 23 is provided between the embedded layer 14B and the active layer 15 and has a function to adjust coupling efficiency between light propagating in the air hole layer 14P and the air hole layer 14P as a resonator. Alternatively, the light distribution adjustment layer 23 may function as a separate confinement heterostructure (SCH) layer used for a bulk structure and a quantum well structure active layer.

In the present embodiment, the light distribution adjustment layer 23 is an undoped In_{0.03}Ga_{0.97}N layer and has a layer thickness of, for example, 50 nm. The composition or refractive index, and the layer thickness of the light distribution adjustment layer 23 are selected in accordance with adjustment of the coupling efficiency.

Note that the n-side semiconductor layer including the n-side guide layer 14 and the light distribution adjustment layer 23 is also referred to as a first semiconductor layer, but the light distribution adjustment layer 23 may not be provided.

The active layer 15 as a light-emitting layer is, for example, a multiple quantum well (MQW) layer including two quantum well layers. Barrier layers and quantum well layers of a MQW are GaN (layer thickness: 6.0 nm) and InGaN (layer thickness: 4.0 nm), respectively. The emission central wavelength of the active layer 15 is 440 nm.

Note that the active layer 15 is preferably disposed within 180 nm from the air hole layer 14P (in other words, within a period PK of the air holes). In this case, a high resonance effect due to the air hole layer 14P is obtained.

The p-side guide layer 16 is constituted by a p-side guide layer (1) 16A as an undoped In_{0.02}Ga_{0.98}N layer (layer thickness: 70 nm), and a p-side guide layer (2) 16B as an undoped GaN layer (layer thickness: 180 nm).

The p-side guide layer 16 is an undoped layer in consideration of light absorption due to dopants (such as magnesium (Mg) ), but may be doped to achieve favorable electrical conductivity. Moreover, the In composition and layer thickness of the p-side guide layer (1) 16A may be selected as appropriate to adjust electric field distribution in an oscillation operation mode.

The electron blocking layer (EBL) 17 is a p-type Al_{0. 2}Ga_{0.8}N layer doped with magnesium (Mg) and has a layer thickness of 15 nm, for example.

The p-cladding layer 18 is a Mg-doped p-Al_{0. 06}Ga_{0. 94}N layer and has a layer thickness of, for example, 600 nm. The Al composition of the p-cladding layer 18 is preferably selected such that its refractive index is lower than that of the p-side guide layer 16. The p-cladding layer 18 functions as a first p-cladding layer.

The p-contact layer 19 is a Mg-doped p-GaN layer and has a layer thickness of, for example, 20 nm. The carrier concentration of the p-contact layer 19 is set to a concentration that allows ohmic contact with a light-transmissive electrode 29 that is a light-transmissive electric conductor layer provided on its surface. P-type or undoped InGaN may be used in place of p-type GaN. Alternatively, a layer in which a GaN layer and an InGaN layer are stacked may be used.

Note that a layer constituted by the p-side guide layer 16, the electron blocking layer 17, the p-cladding layer 18, and the p-contact layer 19 is also referred to as a second semiconductor layer.

Note that, in the present specification, “n-side” and “p-side” do not necessarily mean that the corresponding components have n-type or p-type conductivity. For example, an n-side guide layer means a guide layer provided on the n-side of the active layer and may be an undoped layer (or i-layer).

The n-cladding layer 13 may be constituted by a plurality of layers instead of a single layer, and in this case, not all layers need to be n-layers (n-doped layers) but undoped layers (i-layers) may be included. This applies to the p-side guide layer 16 and the p-cladding layer 18 as well.

Not all semiconductor layers described above need to be provided, but the configuration only needs to include the first semiconductor layer of the first conduction type, the second semiconductor layer of the second conduction type, and the active layer (light-emitting layer) sandwiched between these layers.

In the present embodiment, description is made on a case where the air hole layer 14P (photonic crystal layer) is provided in the first semiconductor layer (n-type semiconductor layer), but the air hole layer may be provided in the second semiconductor layer (p-type semiconductor layer).

A light-transmissive electrode/Ag/Au layer in which the light-transmissive electrode 29 (not illustrated), a silver (Ag) layer, and a gold (Au) layer are sequentially stacked is formed as a p-electrode 20B (second electrode) on the p-contact layer 19. Specifically, the p-electrode 20B functions as a light reflective layer, and the interface between the light-transmissive electrode 29 and the Ag layer of the p-electrode 20B is a reflection surface SR. Note that the reflection surface SR is provided in parallel to the air hole layer 14P.

The p-electrode 20B has a circular shape with a diameter RA centered at the central axis CX of an air hole formation region 14R. Specifically, the light-transmissive electrode 29 has the diameter RA=300 μm, for example, when viewed from top (in other words, when viewed in a direction perpendicular to the semiconductor structure layer 11). Note that Pd, Al, an Al alloy, or the like may be used as the p-electrode 20B. In addition, a pad electrode or the like may be provided on the p-electrode 20B.

The light-transmissive electrode 29 is formed of a light-transmissive electric conductor and is formed of, for example, indium tin oxide (ITO). Note that the light-transmissive electrode 29 is not limited to ITO but may be a light-transmissive electric conductor such as zinc tin oxide (ZTO), GZO (ZnO:Ga), or AZO (ZnO:Al).

The side surface and upper surface of the semiconductor structure layer 11 and the side surface of the p-electrode 20B are covered with an insulating film 21 of SiO₂ or the like. The insulating film 21 is formed so as to extend over the p-electrode 20B and cover an edge part of the upper surface of the p-electrode 20B.

The insulating film 21 also functions as a protective film and protects a crystal layer containing aluminum (Al), which constitutes the PCSEL element 10, from corrosive gas and the like. The insulating film 21 also prevents short-circuit and the like due to adhered object or soldering creep during mounting, thereby contributing to improvement of reliability and yield.

The material of the insulating film 21 is not limited to SiO₂ but may be selected from among ZrO₂, HfO₂, TiO₂, Al₂O₃, SiNx, Si, and the like.

A circularly annular cathode electrode 20A (first electrode) is formed on the back surface of the element substrate 12 (refer to FIG. 2C). An antireflection (AR) coat layer 27 is formed inside the cathode electrode 20A.

The cathode electrode 20A is made of Ti/Au and in ohmic contact with the element substrate 12. The electrode material may be selected from among Ti/Al, Ti/Rh, Ti/Al/Pt/Au, Ti/Pt/Au, and the like in addition to Ti/Au.

Radiated light from the active layer 15 is diffracted by the air hole layer (PC layer) 14P. Light (directly diffracted light Ld: first diffracted light) diffracted by the air hole layer 14P (diffraction surface WS) and directly emitted from the air hole layer 14P, and light (reflected diffracted light Lr: second diffracted light) emitted by diffraction through the air hole layer 14P and reflected by the reflection surface SR are externally emitted from a light emission region 20L (FIG. 2C) on the back surface (emission surface) 12R of the element substrate 12.

As illustrated in FIG. 2B, the air holes 14K in the air hole layer 14P are periodically arrayed and provided in the quadrilateral air hole formation region 14R, for example. As illustrated in FIG. 2C, an anode region RA is formed so as to be included in the air hole formation region 14R.

The cathode electrode 20A is provided as an annular electrode outside the p-electrode 20B such that it does not overlap the p-electrode 20B when viewed in a direction perpendicular to the air hole layer 14P.

A region inside the cathode electrode 20A is the light emission region 20L. A bonding pad 20C that is electrically connected to the cathode electrode 20 and connected to a wire for power supply from outside is provided.

### 2. Method for Producing Air Hole Layer and Recrystallization Growth

A process for producing the air hole layer and recrystallization growth will be described below. The metalorganic vapor phase epitaxy (MOVPE) method was used as the crystal growth method. Note that a method for forming the air hole layer 14P will be described below using, as an example, a case where the air hole layer 14P is a double-lattice photonic crystal layer, but a single-lattice photonic crystal layer and a multiple-lattice photonic crystal layer can be formed in the same manner.

### (a) Manufacturing Flow

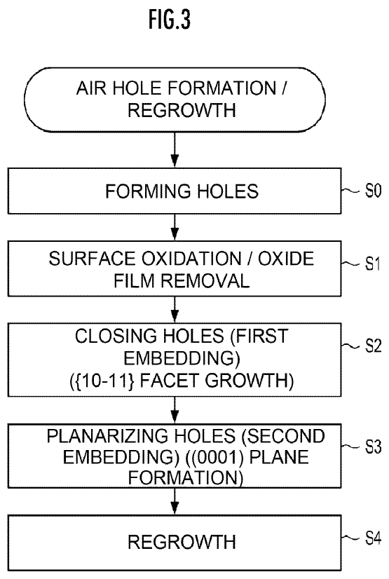

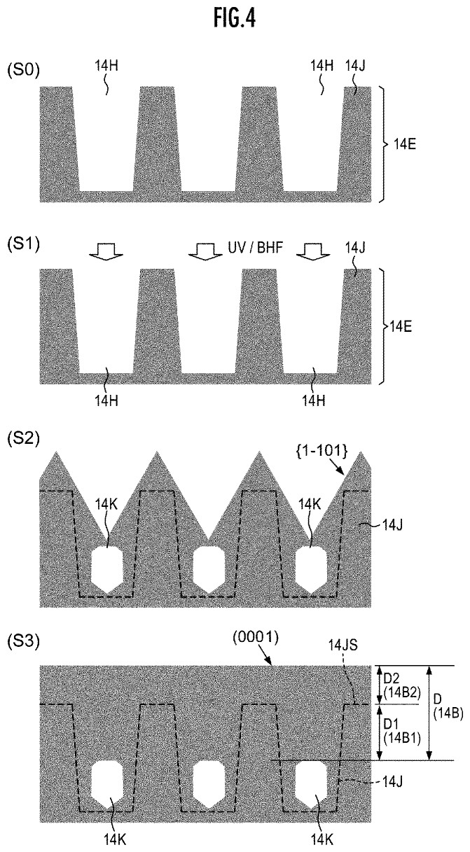

FIG. 3 is a flowchart illustrating a method for manufacturing the PCSEL element 10. The following describes, in detail with reference to FIG. 3, a process for manufacturing the PCSEL element 10, in which air holes (air-holes) of the air hole layer are formed by performing embedding growth in recesses (holes), and subsequently the active layer and the p-side guide layer are grown.

FIG. 4 is a cross-sectional view schematically illustrating a section of the n-side guide layer 14 at formation steps S0 to at S3 of the embedded layer 14B. Note that, in FIG. 4, for ease of description and understanding, a case where the air hole layer 14P is a single-lattice photonic crystal layer is illustrated and described, but a multiple-lattice photonic crystal layer can also be formed in the same manner.

The following describes, in detail with reference to FIGS. 3 and 4, the embedded layer 14B (stacked embedded layer) formed by recrystallization growth on air holes.

### (Step S0) Hole Formation

First, an n-type Al_{0. 04}Ga_{0. 96}N layer having an Al composition of 4% was grown as the n-cladding layer 13 on the element substrate 12. Subsequently, as illustrated in FIG. 4, a hole formation preparation layer 14E that is an n-type GaN layer was grown on the n-cladding layer 13. The hole formation preparation layer 14E is a preparation layer for forming the lower guide layer 14A and the air hole layer 14P including air holes. The hole formation preparation layer 14E has a surface (upper surface) made of a flat (0001) plane.

After the above-described hole formation preparation layer 14E was formed, the substrate was taken out of a chamber of a MOVPE device, and minute recesses (holes) were formed on the surface of the grown layer. After a clean surface was obtained by cleaning, a silicon nitride film (SiNₓ) was deposited by using plasma CVD. A resist for electron beam lithography was applied thereon, and the substrate was placed in an electron beam lithography device and subjected to patterning of a two-dimensional periodic structure.

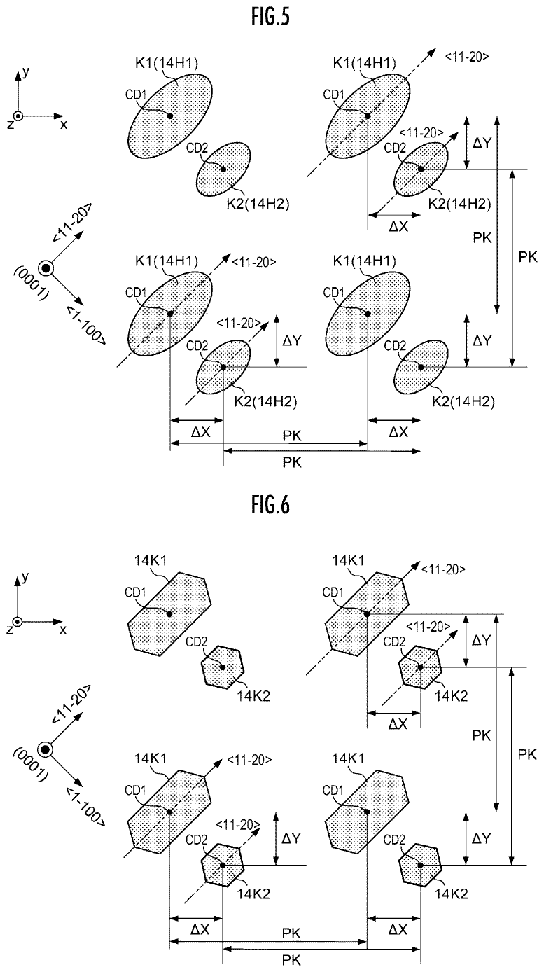

FIG. 5 is a plan view schematically illustrating main openings K1 and sub openings K2 of the resist, and main holes 14H1 and sub holes 14H2 after etching. As illustrated in FIG. 5, patterning was performed such that opening pairs, each consisting of an oval main opening K1 and a smaller sub opening K2 than the main opening Kl, were two-dimensionally arrayed in a square lattice shape with the period PK in the plane of the resist. Note that the openings are hatched for clarity of the drawing.

More specifically, the main openings K1 are two-dimensionally arrayed such that their centroids CD1 are positioned at lattice points of a square lattice with the period PK in two directions (x direction and y direction) orthogonal to each other. Similarly, the sub openings K2 are two-dimensionally arrayed such that their centroids CD2 are positioned at lattice points of a square lattice with the period PK in the x and y directions.

The major axes of the main openings K1 and the sub openings K2 are parallel to the <11-20> direction of crystal orientation, and the minor axes of the main openings K1 and the sub openings K2 are parallel to the <1-100> direction.

The centroids CD2 of the sub openings K2 are offset from the centroids CD1 of the main openings K1 by Δx and Δy. In this example, Δx=Δy. In other words, the centroids CD2 of the sub openings K2 are offset from the centroids CD1 of the main openings K1 in the <1-100> direction.

The distances Δx and Δy between the centroids of the main openings K1 and the sub openings K2 were set to Δx=Δy=0.46PK. After the patterned resist was developed, the SiNₓ film was selectively dry-etched by using an inductive coupled plasma reactive ion etching (ICP-RIE) device. Accordingly, the main openings K1 and the sub openings K2 two-dimensionally arrayed at lattice points of a square lattice with the period PK were formed so as to penetrate through the SiNₓ film.

Note that the period (air hole interval) PK was set to PK=177.5 nm to obtain an oscillation wavelength (λ) of 438 nm.

Subsequently, the resist was removed, and recesses (holes) were formed in a GaN surface portion by using the patterned SiNₓ film as a hard mask. In the ICP-RIE device, GaN was dry-etched in the depth direction by using chlorine-based gas and argon gas, thereby forming the main holes 14H1 and the sub holes 14H2, which are elongated cylindrical recesses etched perpendicularly to the GaN surface.

Note that the recesses (holes) etched in the GaN surface portion by the above-described etching are simply referred to as “holes” to distinguish them from the air holes (air-holes) in the air hole layer 14P. When the main holes 14H1 and the sub holes 14H2 are not particularly distinguished, they are also collectively referred to as holes 14H.

Note that the shape of each hole 14H is not limited to an elongated cylindrical shape but may be a cylindrical shape, a polygonal shape, or the like.

Through the above-described process, the holes 14H were formed in the hole formation preparation layer 14E and a hole formation layer 14J was formed (S0 in FIG. 4).

### (Step S1) Surface Oxidation/Oxide Film Removal

The substrate in which the holes 14H were formed was degrease-cleaned, and then the SiNₓ film was removed by using buffered hydrofluoric acid (BHF).

After the SiNₓ film was removed, O₂ gas was flowed at room temperature while ultraviolet light (UV light) is irradiated to activate O₂ gas, and the surface of the hole formation layer 14J was subjected to oxidation treatment (10 minutes) with generated ozone. Accordingly, SiO₂ (glass) was formed on the upper surface of the hole formation layer 14J and surfaces in the holes 14H.

After the ozone treatment was performed, the substrate was immersed in buffered hydrofluoric acid (BHF) to remove an oxide film formed on the surface. Through the above-described process, Si bonded to Ga was removed.

Finally, the substrate was immersed for 10 minutes in a semiconductor cleaning solution (SemicoClean23 manufactured by Furuuchi Chemical) containing tetramethylammonium hydroxide (TMAH) at 1% approximately, and was rinsed thereafter.

(Step S2) Hole closure: First Embedding Growth

Subsequently, the substrate (FIG. 4) in which the holes 14H were formed (step S0) and that was subjected to the surface oxidation/oxide film removal process (step S1) was degrease-cleaned and then introduced into a reactor of the MOVPE device again to perform recrystallization growth. Specifically, ammonia (NH₃) and trimethylgallium (TMG) were supplied to perform first embedding growth by facet growth, thereby closing openings of the holes 14H.

Specifically, the first embedding growth was performed at a first temperature (920 °C) at which the shapes of the holes 14H are deformed by mass transport into shapes constituted by thermally stable faces.

More specifically, in this first temperature region, N atoms adhere to the outermost surface of the growth substrate, and accordingly, N-polar surfaces are selectively grown. As a result, as illustrated in FIG. 4, crystals with surfaces of {1-101} facets are selectively grown. The holes 14H are closed and embedded (facet growth) as opposing {1-101} facets meet each other. The first embedding growth is performed by such facet growth, and the air holes 14K are formed corresponding to the holes 14H.

Note that the hole formation layer 14J (GaN layer) before the embedded layer 14B is formed is illustrated with dashed lines in FIG. 4.

### (Step S3) Planarizing Embedding: Second Embedding Growth

Subsequently, the second embedded layer 14B2 having a thickness of 50 nm was grown after the holes 14H were closed by the facet growth. The growth of the second embedded layer 14B2 was performed by supplying trimethylgallium (TMG) and NH₃ after raising the substrate temperature (growth temperature) to 1050 °C (second embedding temperature). Note that the second embedding temperature was higher than a first embedding temperature. However, the temperature relation between the second embedding temperature and the first embedding temperature may be reversed as long as the growth can be performed with a (0001) plane as the growth surface of the second embedded layer 14B2.

As illustrated in FIG. 4, mass transport was caused by thermal effects and second embedding growth (planarizing embedding growth) was performed to form the second embedded layer 14B2 in which a (0001) plane appears on the surface. The embedded layer 14B was formed by the first embedding growth and the second embedding growth.

Note that, for convenience of description, a layer (including part of the hole formation layer 14J) from the upper surface (surface on a side closer to the active layer 15) of the air hole layer 14P to an upper surface 14JS of the hole formation layer 14J is referred to as the first embedded layer 14B1, and a layer from the upper surface 14JS of the hole formation layer 14J to the planarized surface by the second embedding growth is referred to as the second embedded layer 14B2 (refer to S3 in FIG. 4).

In addition, the entire semiconductor layer (including part of the hole formation layer 14J) from the upper surface of the air hole layer 14P to the upper surface of the second embedded layer 14B2 is referred to as the embedded layer 14B.

The thickness of the first embedded layer 14B1 is defined to be D1, and the thickness of the second embedded layer 14B2 is defined to be D2. Accordingly, the thickness of the embedded layer 14B is given by D=D1+D2.

Note that, in the present specification, the “upper surface” of each semiconductor layer of the n-side guide layer (first guide layer) 14 means a surface on the side closer to the active layer 15.

In the present embodiment, GaN is used for the second embedding growth. The second embedded layer 14B2 also functions as a light distribution adjustment layer for adjusting the coupling efficiency (optical field) between light and the air hole layer 14P.

Specifically, in the present embodiment, undoped GaN is used for the first embedding growth and the second embedding growth. However, the first embedding growth and the second embedding growth are not limited to GaN but may use n-GaN, n-InGaN, undoped GaN, undoped InGaN, or combination of these semiconductors.

### (Step S4) Recrystallization Growth

Subsequently, the substrate on which etching of the embedded layer 14B was performed was subjected to crystal growth in the reactor for layers on the upper side of the light distribution adjustment layer 23.

Specifically, the light distribution adjustment layer 23 was grown on the second embedded layer 14B2.

Specifically, the light distribution adjustment layer 23 is an undoped In_{0.03}Ga_{0.97}N layer and is a semiconductor layer (heterogeneous semiconductor layer) having a crystal composition different from that of the embedded layer 14B (GaN layer).

Subsequently, the active layer 15, the p-side guide layer (second guide layer) 16, the electron blocking layer (EBL) 17, the p-cladding layer 18, and the p-contact layer 19 were sequentially grown on the light distribution adjustment layer 23. Through the above-described process, the PCSEL element 10 was produced.

### (b) Air Hole Layer

Through the above-described embedding process, the air hole layer 14P was formed in a double-lattice structure in which the air holes 14K, each constituted by a pair of a main air hole 14K1 and a sub air hole 14K2, are two-dimensionally disposed at respective square lattice points. The sub air holes 14K2 have smaller air hole radii and heights than those of the main air holes 14K1. In the present invention, the upper surfaces of the air holes in the air hole layer 14P having a multiple-lattice structure mean upper surfaces (in other words, air holes having shallower upper surfaces) closer to the upper layer (active layer) among the upper surfaces of the main air holes 14K1 and the sub air holes 14K2. Note that the air holes 14K are not limited to a configuration with the main air holes 14K1 and the sub air holes 14K2 having different sizes (air hole pairs), but may have a configuration in a single-lattice structure in which air holes having the same size are two-dimensionally disposed at respective square lattice points.

FIG. 6 is a diagram schematically illustrating a section of the formed air hole layer 14P, which is perpendicular to the central axis CX. In a case where the holes 14H are embedded in a group III nitride, the shapes of the holes 14H are deformed by mass transport into shapes constituted by thermally stable faces, thereby forming the air holes 14K.

Specifically, in the +c plane substrate, the inner side surfaces of the holes 14H undergo shape change into (1-100) planes (in other words, m surface). Specifically, the shapes change from elongated cylindrical shapes to elongated hexagonal prismatic air holes 14K having side surfaces constituted by m planes.

The formed main air holes 14K1 each had an elongated hexagonal prismatic shape having a major radius of 72.5 nm and a minor radius of 43.5 nm at the major radius/minor radius ratio of 1.67. The sub air holes 14K2 each had an elongated hexagonal prismatic shape having a major radius of 44.6 nm and a minor radius of 38.3 nm at the major radius/minor radius ratio of 1.16 and closer to a regular hexagonal prism than the main air holes 14K1.

It was also checked that the distances Δx and Δy between the centroids of the main air holes 14K1 and the sub air holes 14K2 were 81.6 nm (Δx=Δy=0.46PK), which were not changed from before embedding. In addition, it was checked that the major axes of the main air holes 14K1 and the sub air holes 14K2 were parallel to the <11-20> axis (in other words, the a-axis).

Air hole filling factors FF1 and FF2 of the main air holes 14K1 and the sub air holes 14K2 were found to be FF1=8.8% and FF2=4.2% by calculation. An air hole filling factor is the ratio of the area occupied by each air hole per unit area in a two-dimensionally ordered array. Specifically, in a case where the areas of the main air holes 14K1 and the sub air holes 14K2 in the air hole layer 14P are represented by S1 and S2, respectively, the air hole filling factors FF1 and FF2 of the main air holes 14K1 and the sub air holes 14K2 are given by an expression below.
FF1=S1/PK² and FF2=S2/PK²

Through the above-described process, formation of the n-side guide layer 14 including the air hole layer 14P that is an air hole layer is completed.

### 3. Effects of Surface Oxidation/Oxide Film Removal

### (a) Reduction of Interface Si Concentration

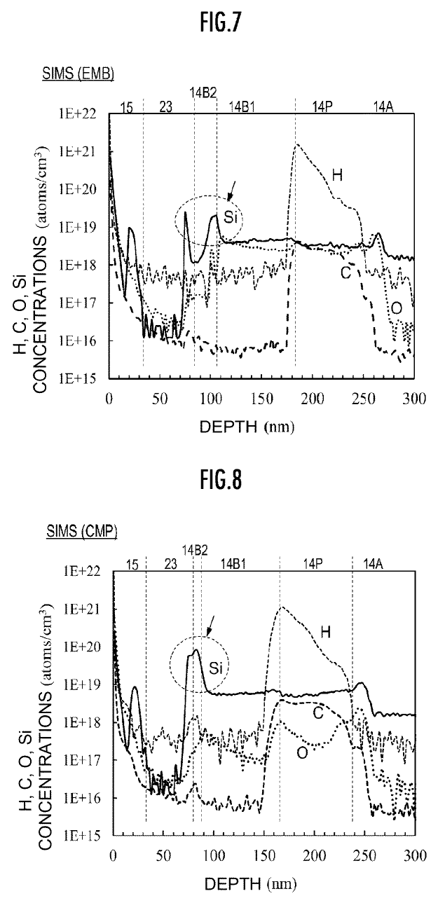

FIG. 7 illustrates SIMS (secondary ion mass spectrometry) measurement results (SIMS profiles) of the PCSEL element 10 (EMB) in the depth direction, which was manufactured by performing the surface oxidation/oxide film removal process (step S1) on the substrate in which the holes 14H are formed. Note that, for clarity of the diagram, semiconductor layers are represented by their reference signs. For example, “14B1” represents the first embedded layer 14B1, “14B2” represents the second embedded layer 14B2, and “23” represents the light distribution adjustment layer 23.

FIG. 8 illustrates depth-direction SIMS profiles of a PCSEL element (CMP) manufactured without performing the surface oxidation/oxide film removal process (step S1).

In the PCSEL element (CMP) without the surface oxidation/oxide film removal, Si at a high concentration of 1×10²⁰ cm⁻³ approximately existed at the interface between the first embedded layer 14B1 and the second embedded layer 14B2 and the interface between the second embedded layer 14B2 and the light distribution adjustment layer 23.

However, as illustrated in FIG. 7, the Si concentration at the interfaces can be reduced to 2×10¹⁹ cm⁻³ approximately (approximately ¼ or less) by oxidizing Si at the surface through ozone treatment and removing the oxide film through BHF treatment.

### (b) Planarity of Regrown Layer

A large amount of Si due to the SiNₓ film as a hard mask and adhesion of siloxane and the like in air was accumulated on the semiconductor surface where the holes 14H are formed. During crystal growth, surface Si reacts with N to form SiN in a highly reactive nitrogen atmosphere (for example, an atmosphere in which NH₃ is dissociated at high temperature). SiN forms an inversion domain on a GaN surface, accordingly, the polarity of GaN formed in a region contaminated with SiN on the upper surface of the first embedded layer due to facet growth is locally inverted and an inversion domain is formed during shape change due to mass transport in formation of the second embedded layer 14B2, thereby causing significant surface roughness. Furthermore, in a case where Si is doped at a level that forms an inversion domain, point defects are likely to be introduced even when an embedded layer can be grown while surface planarity is maintained.

Thus, with conventional technologies, it is impossible to obtain a growth surface with high planarity, and it is impossible to reduce the oscillation threshold current of a surface-emitting laser element. Furthermore, it is impossible to bring the air hole layer 14P and the active layer 15 sufficiently close to each other, and thus it is difficult to obtain a surface-emitting laser element having favorable characteristics with high coupling efficiency between the air hole layer 14P and the active layer 15.

In addition, a large number of point defects are introduced into the film, which degrades crystalline, making it difficult to obtain a surface-emitting laser element having favorable characteristics.

As described above, by performing surface oxidation and oxide film removal treatment, it is possible to largely reduce the Si concentration at the interfaces, thereby suppressing formation of inversion domains, which enables growth of an active layer with high planarity and high quality.

Accordingly, it is possible to provide a surface-emitting semiconductor laser element having a low threshold and high efficiency.

### Second Embodiment

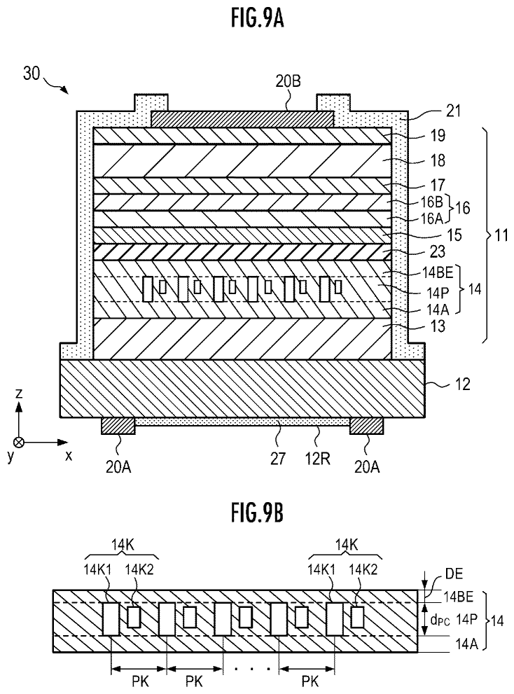

FIG. 9A is a cross-sectional view schematically illustrating an example of the structure of a photonic-crystal surface-emitting laser element (PCSEL element) 30 according to a second embodiment. FIG. 9B is an enlarged cross-sectional view schematically illustrating the air hole layer 14P in FIG. 9A and the air holes 14K arrayed in the air hole layer 14P.

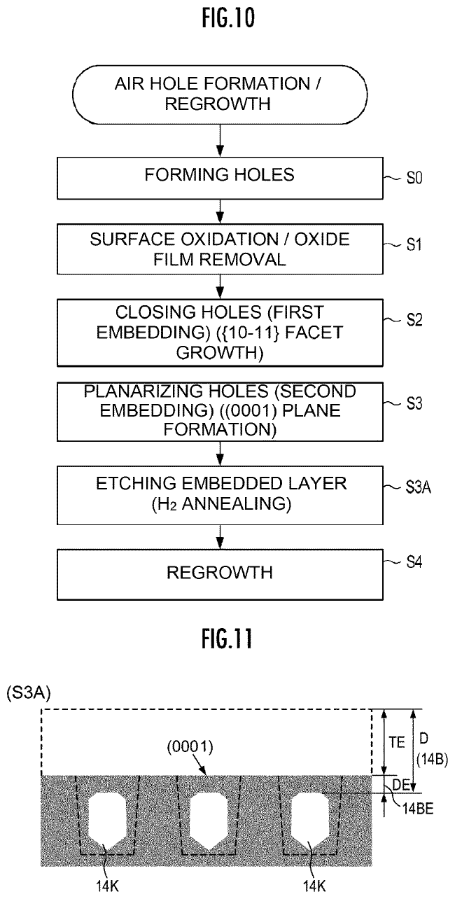

FIG. 10 is a flowchart illustrating a method for manufacturing the PCSEL element 30 of the second embodiment. Note that any same process as in the method for manufacturing the PCSEL element 10 of the first embodiment is denoted by the same reference sign.

FIG. 11 is a cross-sectional view schematically illustrating a section of the n-side guide layer 14 at step S3A in the manufacturing method.

### (a) Manufacturing Method and Structure of PCSEL Element

As illustrated in FIG. 10, in the PCSEL element 30, after surface oxidation and oxide film removal treatment (step S1) were performed, the embedded layer 14B was grown (steps S2 and S3), and subsequently, the embedded layer 14B was etched by H₂ annealing (step S3A).

More specifically, as illustrated in FIG. 11, a semiconductor layer on the air hole layer 14P was etched by TE from the surface of the embedded layer 14B (thickness D). The thickness of the remaining embedded layer 14B is DE(=D-TE). Accordingly, the thickness from the upper surfaces of the air holes 14K to the surface (upper surface) of the remaining embedded layer 14B is DE.

In other words, an embedded layer 14BE (embedded layer having a reduced thickness; hereinafter also referred to as thickness-reduced embedded layer) having the thickness DE was formed through the etching at step S3A.

Specifically, the PCSEL element 30 is different from the PCSEL element 10 of the first embodiment in that the PCSEL element 30 includes the thickness-reduced embedded layer 14BE formed by etching, while other aspects are the same as those of the PCSEL element 10 of the first embodiment.

### (b) Thickness Reduction of Embedded Layer: H₂ Annealing and Etching

The surface morphology of the embedded layer 14B (thickness-reduced embedded layer 14BE) when the embedded layer 14B was etched from the surface of the embedded layer 14B by H₂ annealing was evaluated.

Specifically, samples (i) to (iv) were produced by varying the etching time to change the thickness DE of the thickness-reduced embedded layer 14BE (in other words, the embedded layer 14B after etching).

Note that, as described above, the Si concentration at the interfaces is reduced to 2×10¹⁹ cm⁻³ approximately through surface oxidation and oxide film removal treatment.

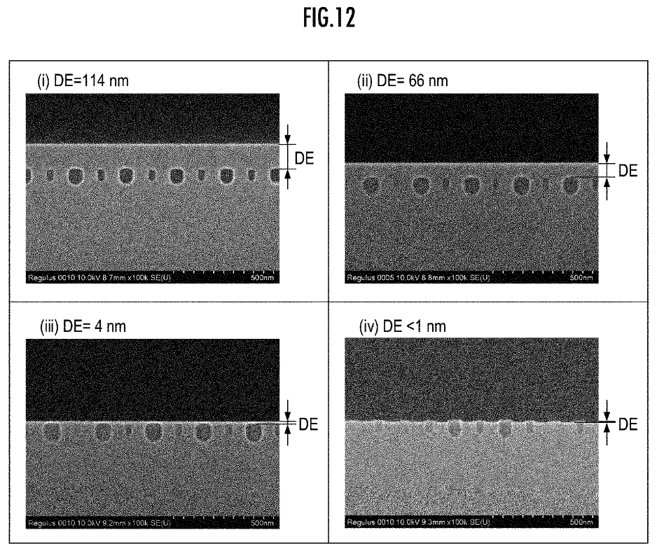

FIG. 12 is SEM images illustrating sections when surfaces of semiconductor layers on which the embedded layer 14B was regrown after the surface oxidation/oxide film removal process (step S1) was performed were etched by H₂ annealing.

As illustrated in FIG. 12, the thickness DE of the thickness-reduced embedded layer 14BE was (i) DE=114 nm, (ii) DE=66 nm, (iii) DE=4 nm, and (iv) DE<1 nm.

In annealing in a hydrogen (H₂) atmosphere, a (0001) plane is a thermally stable face, and it is possible to etch and thin the embedded layer 14B while maintaining surface planarity. Accordingly, an active layer with high planarity and high quality can be grown on the embedded layer 14B. Note that the annealing atmosphere may contain group III materials and group V materials.

More specifically, in a group III nitride semiconductor, desorption of surface atoms occurs and the surface is etched when high-temperature annealing is performed in a H₂ atmosphere. Through this process, since a plane with the slowest etching rate remains, the most thermally stable (0001) plane is formed at the surface. Accordingly, in a case where a +c plane substrate is used, it is possible to perform etching while maintaining the (0001) plane parallel to the substrate. Accordingly, the embedded layer 14B can be thinned, and the spacing (distance) between the air hole layer 14P (air hole layer) and the active layer 15 can be reduced.

The surface morphology of samples (i) to (iv) was observed by using an atomic force microscope (AFM).

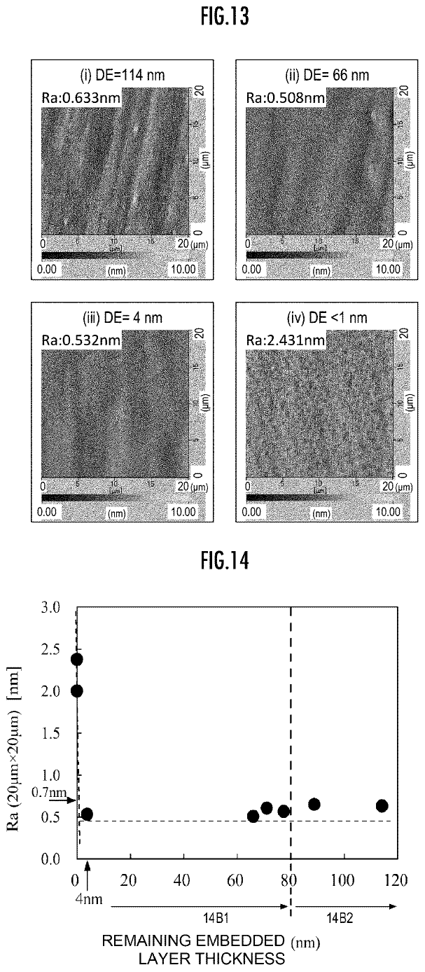

FIG. 13 is a diagram illustrating AFM images of the surfaces of samples (i) to (iv).

The surface roughness in a case where the thickness DE of the thickness-reduced embedded layer 14BE was (i) DE=114 nm, (ii) DE=66 nm, (iii) DE=4 nm, and (iv) DE<1 nm was Ra=0.633 nm, 0.508 nm, 0.532 nm, and 2.43 nm respectively, in a 20 μm×20 μm region.

It was found that sufficiently planarized surfaces can be obtained in the cases of (i) to (iii). It also found that favorable planarity can be obtained in the extremely thinned case with (iii) DE=4 nm. In the case of (iv) DE<1 nm, large surface roughness was observed.

FIG. 14 is a graph plotting the surface roughness Ra in a 20 μm×20 μm region with respect to the thickness DE of the thickness-reduced embedded layer 14BE.

As illustrated in FIG. 14, it is understood that a sufficiently planarized surface can be obtained with DE≥4 nm. More specifically, it can be understood that Ra≤0.7 nm can be obtained for the surface roughness Ra in a 20 μm×20 μm region when the thickness DE of the thickness-reduced embedded layer 14BE is not less than 4 nm.

### (c) Distance Between Air Hole Layer and Active Layer

From the above-described result, it can be understood that the sufficiently planarized active layer 15 can be obtained when the distance between the air hole layer 14P and the active layer 15, in other words, the distance between the upper surfaces of the air holes 14K in the air hole layer 14P and the active layer 15 is not less than 4 nm, and a surface-emitting laser element having favorable characteristics with high coupling efficiency between the air hole layer 14P and the active layer 15 can be obtained.

To obtain high coupling efficiency, the distance between the air hole layer 14P and the active layer 15 is preferably not more than 200 nm.

Moreover, by setting the distance between the air hole layer 14P and the active layer 15 to 4 to 150 nm, it is possible to obtain a surface-emitting semiconductor laser element having higher resonance effect and having a low threshold and high efficiency.

Note that, in a case where the active layer 15 is an active layer in a quantum well structure, the distance between the upper surfaces of the air holes 14K and the active layer 15 means the distance between the upper surfaces of the air holes 14K and a first quantum well layer (in other words, a quantum well layer closest to the air hole layer 14P).

Conventionally, to obtain a high air hole filling factor for an air hole layer having a multiple-lattice structure, an embedded layer thicker than in an air hole layer having a single-lattice structure has been needed in some cases. According to the present invention, even in such a case, it is possible to use a thin embedded layer, thereby obtaining high coupling efficiency (resonance effect) between the air hole layer and the active layer.

According to the present embodiment, the air hole layer 14P and the active layer 15 having high planarity can be provided in proximity. Specifically, as described above, the surface roughness Ra of the embedded layer 14BE satisfies Ra≤0.7 nm when the thickness of the embedded layer 14BE is not less than 4 nm.

Note that, as illustrated in the SIMS measurement results in FIGS. 7 and 8, it can be understood that, at parts where the Si concentration in the first embedded layer 14B1 is flat, the Si concentration is 4.5×10¹⁸ cm⁻³ approximately in a case where oxide film removal (step S1) of the hole formation layer 14J is performed (FIG. 7), which is reduced as compared to 6.0×10¹⁸ cm⁻³ approximately in a case where oxide film removal is not performed (FIG. 8).

Accordingly, it is understood that by performing surface oxidation and oxide film removal of the hole formation layer 14J, the Si concentration in the embedded layer 14B is reduced, which makes it possible to regrow a semiconductor layer having high planarity.

The first and second embodiments are described above in detail. In the case described above in the first and second embodiments, the light distribution adjustment layer 23 is provided, but the active layer 15 may be directly formed on the embedded layer 14B or the embedded layer 14BE without providing the light distribution adjustment layer 23. In this case, the air hole layer 14P and the active layer 15 having high planarity can be provided in closer proximity.

As described above in detail, according to the present invention, it is possible to bring the air hole layer and the active layer into proximity to enhance the resonance effect, and it is possible to provide a method for manufacturing a surface-emitting semiconductor laser element including a high-quality active layer and having a low threshold and high efficiency, and a photonic-crystal surface-emitting laser element.

Note that numerical values in the above-described embodiments are merely exemplary, unless otherwise specified, and may be modified and applied as appropriate. Although examples are described above for a PCSEL element having a double-lattice structure, the present invention is also applicable to a PCSEL element having a single-lattice structure and, in general, to a PCSEL element having a multiple-lattice structure.

The present invention is described above with a photonic crystal layer in which air holes have a hexagonal prismatic shape as an example, but is also applicable to cases where the air holes in the photonic crystal layer have a cylindrical shape, a quadrilateral shape, a polygonal shape, or an irregular prismatic shape such as a teardrop shape.

### REFERENCE SIGNS LIST

10: PCSEL element
12: element substrate
13: first cladding layer
14: first guide layer
14A: lower guide layer
14B: embedded layer
14BE: embedded layer
14B1: first embedded layer
14B2: second embedded layer
14B2: second embedded layer
14E: hole formation preparation layer
14J: hole formation layer
14K: air hole/air hole pair
14K1/14K2: main/sub air hole
14P: photonic crystal layer (air hole layer)
15: active layer
16: second guide layer
17: electron blocking layer
18: second cladding layer
19: contact layer
23: light distribution adjustment layer

1. A method for manufacturing a surface-emitting semiconductor laser element, the manufacturing method comprising:
(a) forming a hole formation preparation layer on a substrate;
(b) forming holes in the hole formation preparation layer, the holes being two-dimensionally disposed at respective lattice points, thereby forming a hole formation layer;
(c) oxidizing a surface of the hole formation layer to form an oxide film and thereafter removing the oxide film;
(d) performing facet growth to close the holes, thereby forming a first embedded layer;
(e) growing a second embedded layer that flatly embeds the first embedded layer, thereby forming a first guide layer including an air hole layer having air holes corresponding to the holes; and
(f) performing crystal growth of a semiconductor layer including an active layer on the first guide layer.

2. A method for manufacturing a surface-emitting semiconductor laser element, the manufacturing method comprising:
(a) forming a hole formation preparation layer on a substrate;
(b) forming holes in the hole formation preparation layer, the holes being two-dimensionally disposed at respective lattice points, thereby forming a hole formation layer,
(c) oxidizing a surface of the hole formation layer to form an oxide film and thereafter removing the oxide film;
(d) performing facet growth to close the holes, thereby forming a first embedded layer;
(e) growing a second embedded layer that flatly embeds the first embedded layer, thereby forming a first guide layer including an air hole layer having air holes corresponding to the holes;
(f) performing planar etching on a surface of the first guide layer by annealing in a hydrogen atmosphere; and
(g) performing crystal growth of a semiconductor layer including an active layer on the planar-etched first guide layer.

3. The manufacturing method according to claim 1, wherein the step of forming the oxide film is a step of oxidizing the surface of the hole formation layer with ozone

4. The manufacturing method according to claim 1, wherein
the surface-emitting semiconductor laser element is a GaN-based semiconductor laser element, and
a Si concentration at an interface between the first guide layer and the semiconductor layer including the active layer is not more than 2×10¹⁹ cm⁻³.

5. The manufacturing method according to claim 1, wherein
the surface-emitting semiconductor laser element is a GaN-based semiconductor laser element,
a crystal growth surface of the substrate is a {0001} plane, and
a facet surface of the facet growth is a {1-101} plane.

6. The manufacturing method according to claim 1, wherein a distance from upper surfaces of the air holes of the air hole layer to the active layer is not more than 200 nm.

7. The manufacturing method according to claim 2, wherein a thickness of the second embedded layer on an upper surface of the hole formation layer after the planar etching is not less than 4 nm.

8. A surface-emitting semiconductor laser element comprising:
an n-type semiconductor layer;
a first guide layer formed on the n-type semiconductor layer and including an air hole layer having air holes two-dimensionally disposed at respective lattice points and an embedded layer formed on the air hole layer and closing the air holes;
a semiconductor layer formed on the embedded layer and including an active layer; and
a second guide layer formed on the semiconductor layer including the active layer,
wherein a distance from upper surfaces of the air holes of the air hole layer to the active layer is 4 to 200 nm.

9. The surface-emitting semiconductor laser element according to claim 8, wherein a surface roughness Ra of the embedded layer satisfies Ra≤0.7 nm.

10. The surface-emitting semiconductor laser element according to claim 8, wherein
the active layer has a quantum well structure, and
the distance to the active layer is a distance between a quantum well closest to the air hole layer and upper surfaces of the air holes.

11. The surface-emitting semiconductor laser element according to claim 8, wherein the semiconductor layer including the active layer includes a heterogeneous semiconductor layer provided between the embedded layer and the active layer and having a crystal composition different from a crystal composition of the embedded layer.

12. The surface-emitting semiconductor laser element according to claim 11, wherein
the embedded layer includes a first embedded layer closing the air holes, and a second embedded layer provided on the first embedded layer, and
at a first interface that is an interface between the first embedded layer and the second embedded layer and at a second interface that is an interface between the second embedded layer and the heterogeneous semiconductor layer, Si concentrations contained in the first interface and the second interface are not more than 2×10¹⁹ cm⁻³.

13. The manufacturing method according to claim 2, wherein the step of forming the oxide film is a step of oxidizing the surface of the hole formation layer with ozone.

14. The manufacturing method according to claim 2, wherein
the surface-emitting semiconductor laser element is a GaN-based semiconductor laser element, and
a Si concentration at an interface between the first guide layer and the semiconductor layer including the active layer is not more than 2×10¹⁹ cm⁻³.

15. The manufacturing method according to claim 2, wherein
the surface-emitting semiconductor laser element is a GaN-based semiconductor laser element,
a crystal growth surface of the substrate is a {0001} plane, and
a facet surface of the facet growth is a {1-101} plane.

16. The manufacturing method according to claim 2, wherein a distance from upper surfaces of the air holes of the air hole layer to the active layer is not more than 200 nm.
